(19) United States
(12) Patent Application Publication
(10) Pub. No.: US 2016/0141446 A1
(43) Pub. Date: May 19, 2016

(54) METHOD FOR MANUFACTURING LIGHT EMITTING DEVICE

(71) Applicant: PlayNitride Inc., Tainan City (TW)

(72) Inventors: Shao-Hua Huang, Tainan City (TW); Yun-Li Li, Tainan City (TW)

(21) Appl. No.: 14/924,718

(22) Filed: Oct. 28, 2015

Related U.S. Application Data
(60) Provisional application No. 62/081,503, filed on Nov. 18, 2014.
(60) Provisional application No. 62/092,265, filed on Dec. 16, 2014.

(30) Foreign Application Priority Data
May 6, 2015 (TW) 104114433

(51) Int. Cl. H01L 33/00; H01L 33/50; H01L 33/62

(52) U.S. Cl. CPC H01L 33/005; H01L 33/62; H01L 33/50

(57) ABSTRACT

A method for manufacturing a light emitting device is provided. Step (a): A semiconductor wafer having a substrate and at least one epitaxial structure is provided. Step (b): An electrode connection layer is formed on the epitaxial structure, wherein the electrode connection layer includes connection pads, first electrodes and second electrodes. Step (c): A package substrate having the similar size as that of the semiconductor wafer and having conductive through holes is provided. Step (d): The semiconductor wafer and the package substrate are bonded by aligning the connection pads with the conductive through holes, so that the conductive through holes are electrically connected to a first type semiconductor layer or a second type semiconductor layer of the epitaxial structure. Step (e): The substrate is removed so as to expose a surface of the epitaxial structure and form a light emitting device.

### CROSS-REFERENCE TO RELATED APPLICATION

This application claims the priority benefits of U.S. provisional application Ser. No. 62/081,503, filed on Nov. 18, 2014, U.S. provisional application Ser. No. 62/092,265, filed on Dec. 16, 2014 and Taiwan application serial no. 104114433, filed on May 6, 2015. The entirety of each of the above-mentioned patent applications is hereby incorporated by reference herein and made a part of this specification.

### BACKGROUND OF THE INVENTION

1. Field of the Invention

The invention relates to a light emitting device, and particularly relates to a method for manufacturing a light emitting device.

2. Description of Related Art

Generally, a light emitting chip is composed of a substrate, an epitaxial structure, N-type electrodes and P-type electrodes, where the N-type electrodes and the P-type electrodes respectively contact an N-type semiconductor layer and a P-type semiconductor layer. In order to expand the application of the light emitting chip, the manufactured light emitting chip is generally disposed on a carrier, and a molding compound is used to package the light emitting chip to form a light emitting package. The carrier is, for example, a printed circuit board or a ceramic substrate, etc., and the carrier has pads corresponding to the N-type electrodes and the P-type electrodes of the light emitting chip. An area of the carrier is greater than an orthogonal projection area of the light emitting chip on the carrier. Namely, an edge of the carrier is larger than an edge of the light emitting chip. Moreover, since the molding compound is, for example, formed on the light emitting chip through dispensing, etc., when the molding compound is used to package the light emitting chip, the molding compound presents an arc shape (for example, a semi-circular or semi-elliptical shape) on the carrier. In this way, the light emitting package has a larger width (i.e. a width of the carrier) and a larger height (i.e. the arc-shaped molding compound). Namely, the light emitting package has a larger volume, which is unable to meet today's demand of thinning and miniaturization of devices. Moreover, each light emitting package is completed by individually packaging the light emitting chip, which is unable to meet a demand of mass production.

### SUMMARY OF THE INVENTION

The invention is directed to a method for manufacturing a light emitting device, by which the light emitting device with a smaller volume is manufactured, and a satisfactory manufacturing efficiency is achieved.

The invention provides a method for manufacturing a light emitting device, which includes following steps. Step (a): a semiconductor wafer including a substrate and at least one epitaxial structure is provided, wherein the epitaxial structure includes a first type semiconductor layer, a second type semiconductor layer and a light emitting layer. The second type semiconductor layer is disposed on the substrate and the first type semiconductor layer is located on the second type semiconductor layer. The light emitting layer is disposed between the first type semiconductor layer and the second type semiconductor layer. Step (b): an electrode connection layer is formed on the epitaxial structure, wherein the electrode connection layer includes a plurality of connection pads, a plurality of first electrodes and a plurality of second electrodes. The first electrodes and the second electrodes are separated from each other and are connected to the corresponding connection pads, and are located at a same side of the epitaxial structure, wherein the first electrodes and the second electrodes are electrically connected to the first type semiconductor layer and the second type semiconductor layer to define a plurality of light emitting units. Step (c): a package substrate having a similar size as that of the semiconductor wafer is provided, wherein the package substrate has a plurality of conductive through holes penetrating through the package substrate. Step (d): the semiconductor wafer and the package substrate are bonded by aligning the connection pads of the electrode connection layer with the conductive through holes, so that the conductive through holes are electrically connected to a first type semiconductor layer or a second type semiconductor layer. Step (e): the substrate is removed to expose a surface of the epitaxial structure, so as to form the light emitting device.

In an embodiment of the invention, the method for manufacturing the light emitting device further includes step (f-1): after the step (e), a cutting process is performed to the light emitting device to form a plurality of sub-light emitting devices, wherein each of the sub-light emitting devices includes a plurality of the light emitting units.

In an embodiment of the invention, the method for manufacturing the light emitting device further includes step (f-2): after the step (e), a cutting process is performed to the light emitting device to form a plurality of sub-light emitting devices, wherein the sub-light emitting devices are separated from each other and an edge of the connection pad of the electrode connection layer is aligned with an edge of the package substrate.

In an embodiment of the invention, the method for manufacturing the light emitting device further includes step (f-3): after the step (e), a sheet-like wavelength converting film is provided, wherein an area of the sheet-like wavelength converting film is greater than that of the package substrate, and the sheet-like wavelength converting film is bonded to the surface of the epitaxial structure of the light emitting device.

In an embodiment of the invention, in the step (f-3), the sheet-like wavelength converting film and the epitaxial structure have micron-scale voids therebetween.

In an embodiment of the invention, in the step (f-3), after the sheet-like wavelength converting film is bonded to the surface of the epitaxial structure of the light emitting device, a color mixing layer is further formed on the sheet-like wavelength converting film.

In an embodiment of the invention, the method for manufacturing the light emitting device further includes step (g): after the step (f-3), a cutting process is performed, and a same cutting device is used to cut the sheet-like wavelength converting film and the light emitting device to form a plurality of sub-light emitting devices.

In an embodiment of the invention, the step (g) is performed in a direction from the sheet-like wavelength converting film to the package substrate.

In an embodiment of the invention, in the step (b), before the electrode connection layer is formed, the method further includes forming an insulation layer on the first type semiconductor layer, wherein the first electrode penetrates through the insulation layer and is electrically connected to the first type semiconductor layer, the second electrode penetrates through the insulation layer, the first type semiconductor layer and the light emitting layer and is electrically connected to the second type semiconductor layer.

In an embodiment of the invention, in the step (d), the connection pads of the semiconductor wafer are melt through heating for bonding to the package substrate.

In an embodiment of the invention, in the step (d), a bonding area between the semiconductor wafer and the package substrate is smaller than a surface area of an upper surface of the package substrate.

In an embodiment of the invention, in the step (e), after the surface of the epitaxial structure is exposed, the method further includes forming an optical coupling layer on the surface of the epitaxial structure.

In an embodiment of the invention, in the step (d), after the semiconductor wafer and the package substrate are bonded, each of the conductive through holes and the corresponding connection pad have at least one space therebetween.

In an embodiment of the invention, in the step (b), a contour of the second electrodes when viewing from atop is a combination of a dot-like profile and a linear profile, and a contour of each of the first electrodes when viewing from atop is a dot-like profile.

According to the above descriptions, the semiconductor wafer having the epitaxial structure formed with the electrode connection layer is bonded to the package substrate through wafer bonding, and then the substrate is removed to form the light emitting device with the area of the package substrate close to the area of the epitaxial structure, and based on power supplied by an external circuit, the light emitting device can be used. Compared to a conventional light emitting package in which electrodes of a light emitting chip are electrically connected to pads on a larger carrier, and power is supplied to the pads through the external circuit, the light emitting device with a smaller volume is manufactured according to the method for manufacturing the light emitting device of the invention. Moreover, since the method for manufacturing the light emitting device of the invention is to perform the cutting process after bonding the semiconductor wafer to the package substrate, the invention is adapted to simultaneously fabricate a plurality of sub-light emitting devices (which is regarded as a light emitting chip), and the sub-light emitting devices only have one cutting mark, and the structure of the light emitting devices is different to the conventional light emitting chip.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1H are cross-sectional views of a light emitting device according to an embodiment of the invention.

FIG. 2A to FIG. 2C are cross-sectional views of partial steps of a method for manufacturing a light emitting device according to an embodiment of the invention.

FIG. 3 is a cross-sectional view of a sub-light emitting device according to another embodiment of the invention.

FIG. 4A, FIG. 4B and FIG. 4C are cross-sectional views of sub-light emitting devices according to three other embodiments of the invention.

FIG. 5 is a cross-sectional view of a sub-light emitting device according to another embodiment of the invention.

FIG. 6 is a cross-sectional view of a sub-light emitting device according to another embodiment of the invention.

FIG. 7 is a cross-sectional view of a sub-light emitting device according to another embodiment of the invention.

FIG. 8A, FIG. 8B and FIG. 8C are cross-sectional views of sub-light emitting devices according to a plurality of embodiments of the invention.

FIG. 9 is a top view of an electrode connection layer of a sub-light emitting device according to another embodiment of the invention.

FIG. 10 is a cross-sectional view of a sub-light emitting device according to another embodiment of the invention.

FIG. 11 is a cross-sectional view of a sub-light emitting device according to another embodiment of the invention.

FIG. 12 is a cross-sectional view of a sub-light emitting device according to another embodiment of the invention.

### DESCRIPTION OF EMBODIMENTS

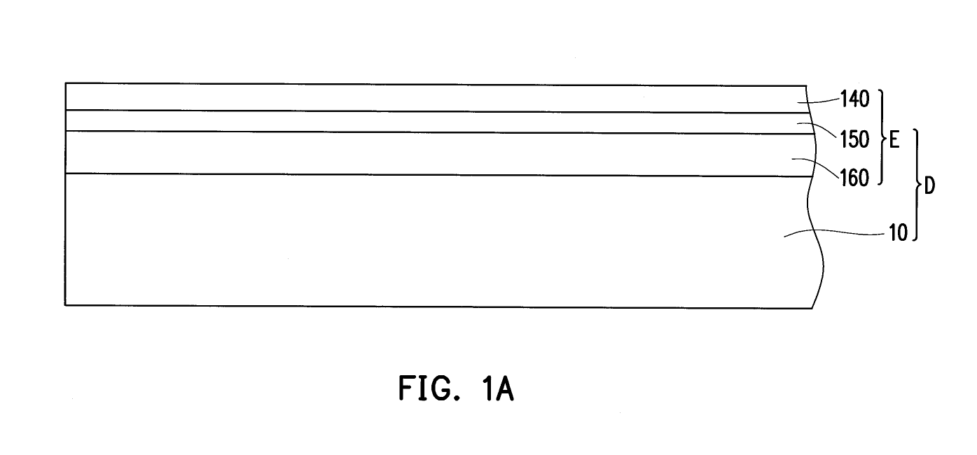

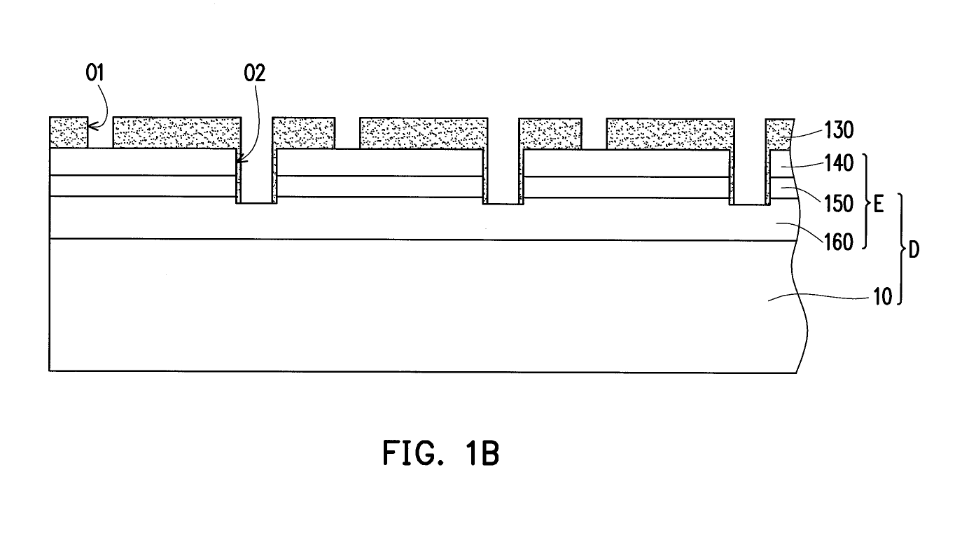

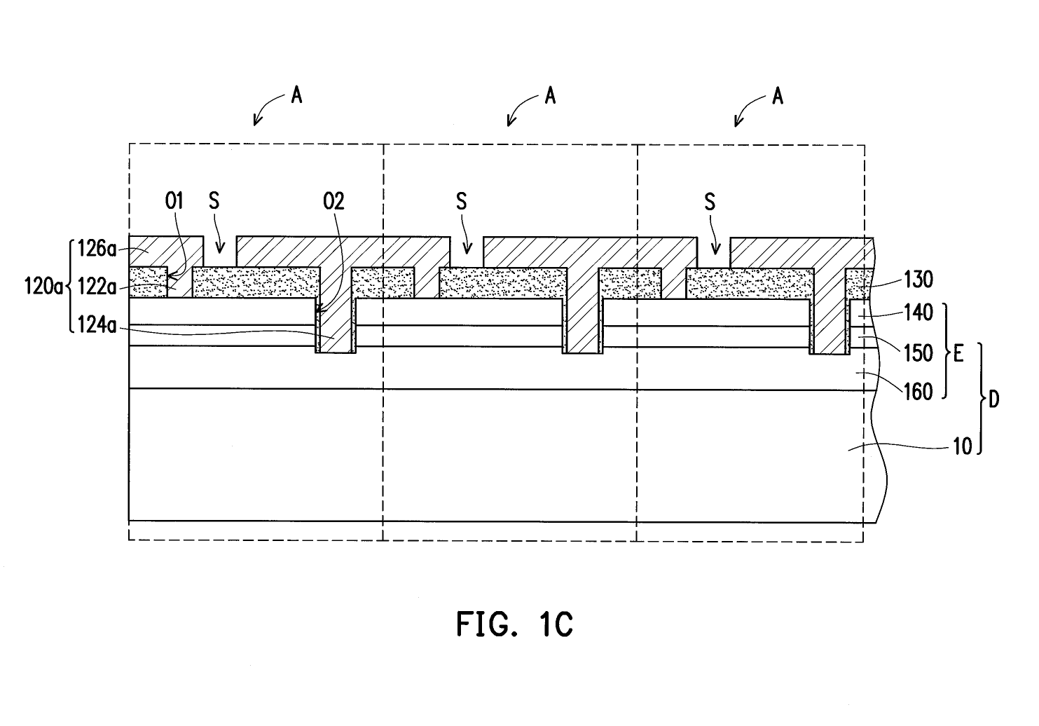

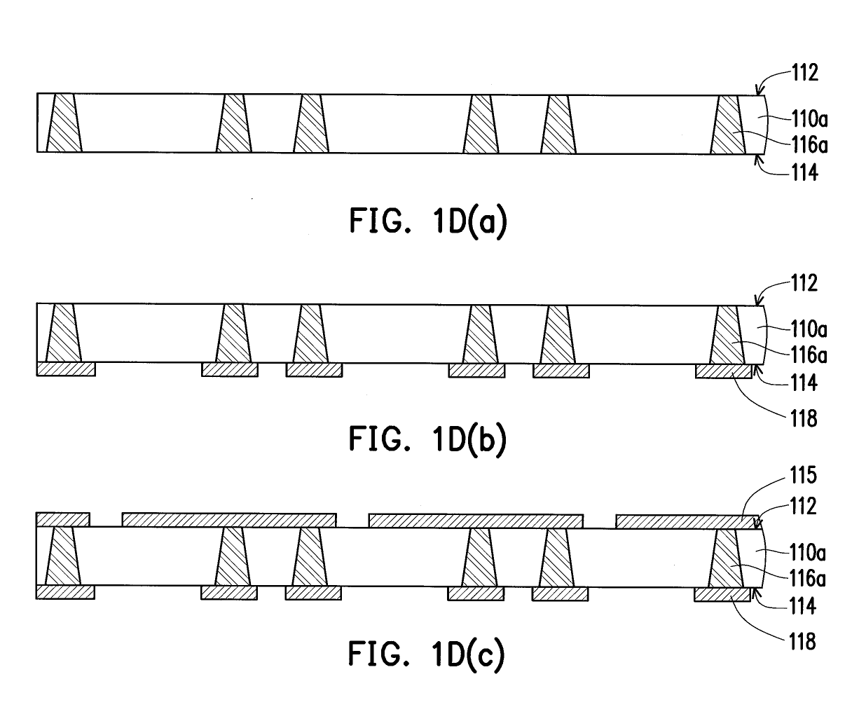

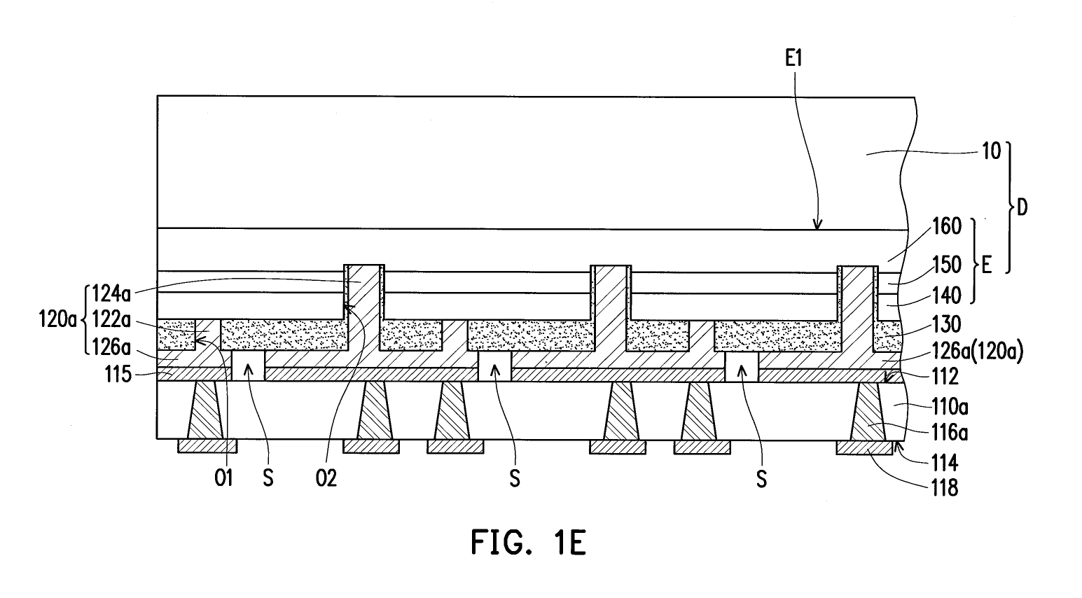

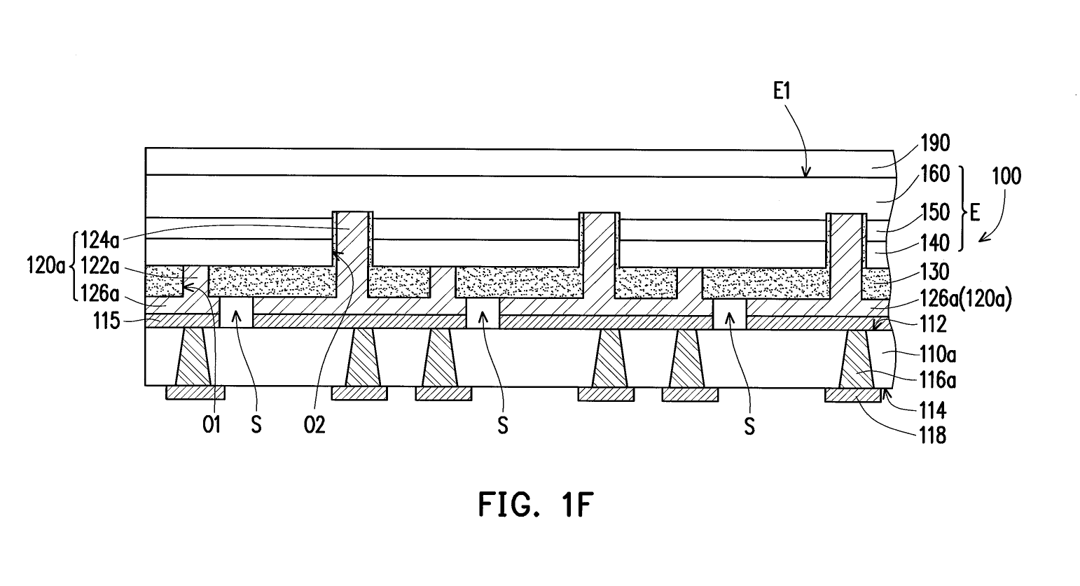

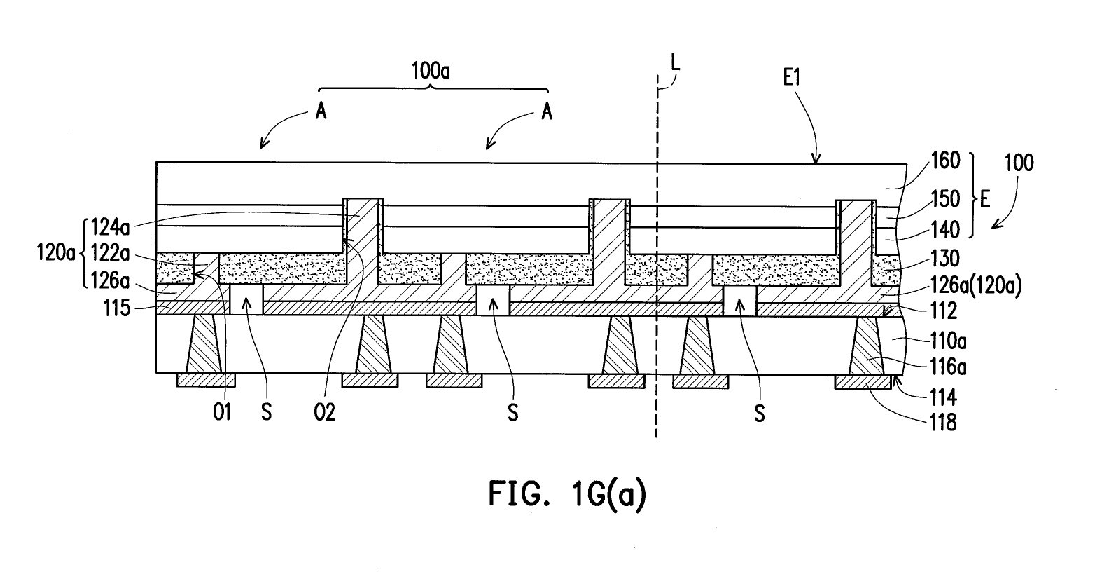

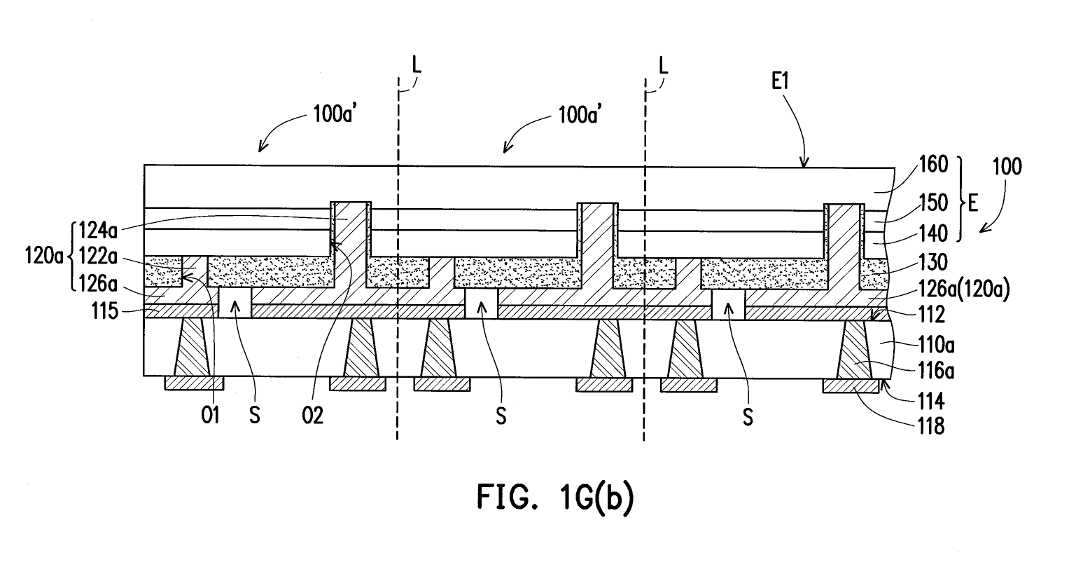

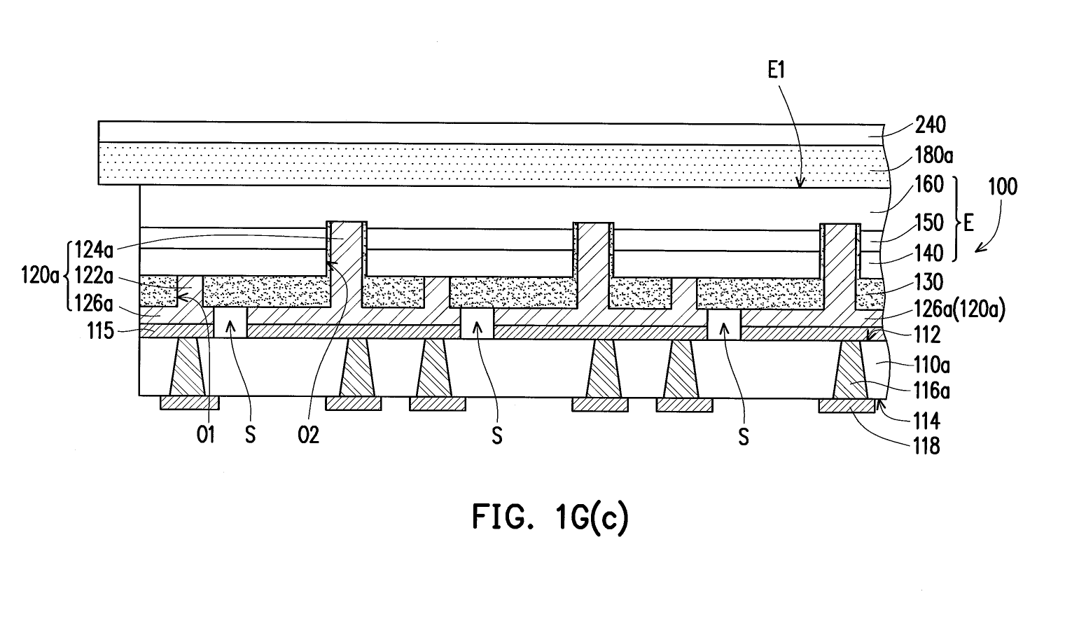

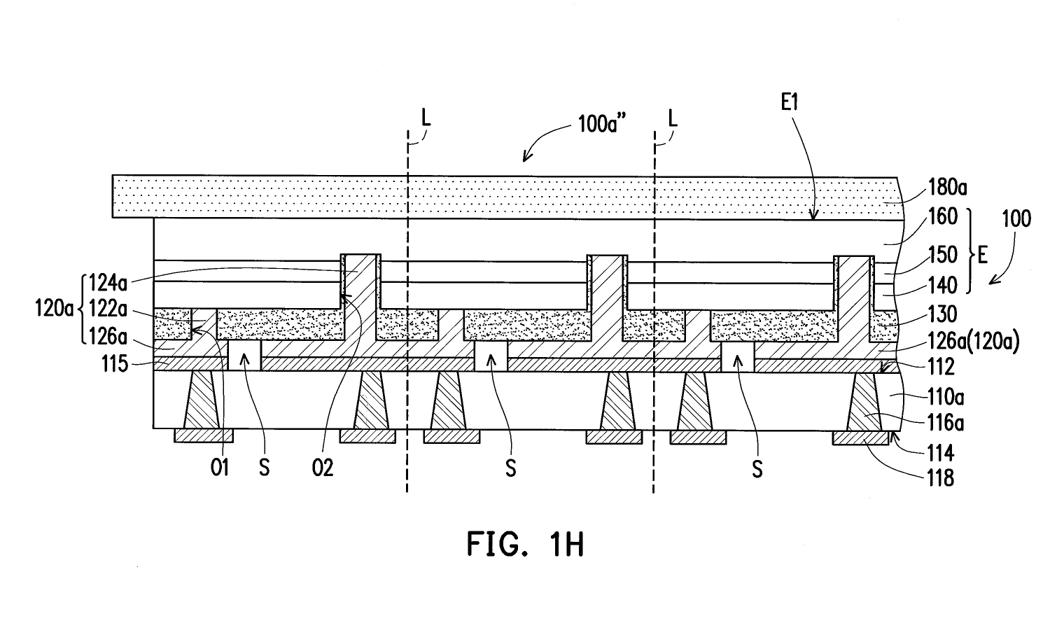

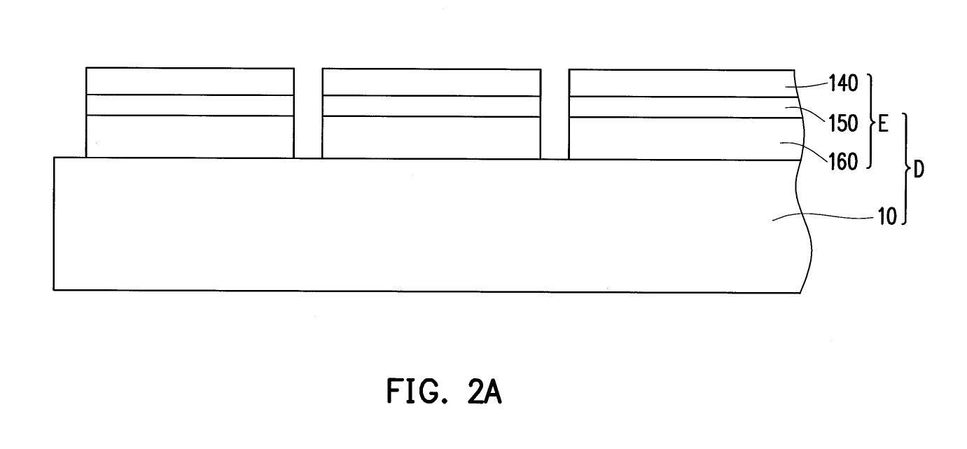

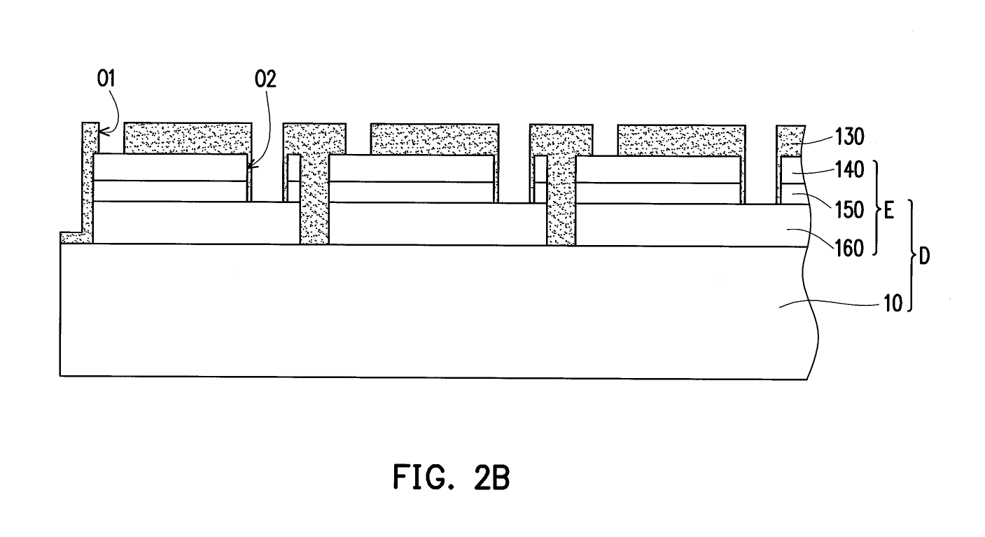

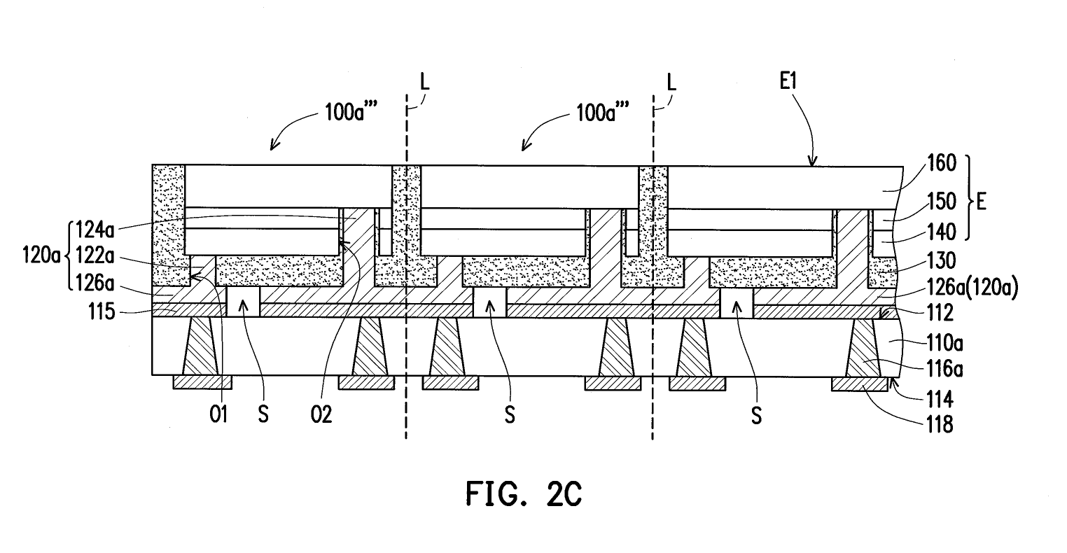

FIG. 1A to FIG. 1H are cross-sectional views of a light emitting device according to an embodiment of the invention. A method for manufacturing the light emitting device of the invention includes following steps. First, referring to FIG. 1A, a semiconductor wafer D is provided, where the semiconductor wafer D includes a substrate 10 and at least one epitaxial structure E. The epitaxial structure E is a continuous planar structure, though the invention is not limited thereto. In another embodiment, referring to FIG. 2A, a plurality of epitaxial structures E separated from each other can also be applied. In detail, the epitaxial structure E is disposed on the substrate 10. As shown in FIG. 1A, the epitaxial structure E includes a first type semiconductor layer 140, a light emitting layer 150 and a second type semiconductor layer 160, where the second type semiconductor layer 160 is disposed on the substrate 10, the first type semiconductor layer 140 is located on the second type semiconductor layer 160, and the light emitting layer 150 is disposed on the second type semiconductor layer 160 and is located between the first type semiconductor layer 140 and the second type semiconductor layer 160. The first type semiconductor layer 140 is, for example, a P-type type semiconductor layer, and the second type semiconductor layer 160 is, for example, an N-type type semiconductor layer, though the invention is not limited thereto. A thickness of the epitaxial structure E is between 3 μm and 15 μm, and preferably between 4 μm and 8 μm.

Then, referring to FIG. 1B to FIG. 1C, an electrode connection layer 120a is formed on the epitaxial structure E. First, referring to FIG. 1B, in order to isolate the electrode structures with different electrical properties, in the method for manufacturing the light emitting device of the present embodiment, before the electrode connection layer 120a is formed, an insulation layer 130 is first formed on the first type semiconductor layer 140. Then, a plurality of first openings O1 and a plurality of second openings O2 are formed on the insulation layer 130 through exposure, developing and etching, where the first opening O1 penetrates through the insulation layer 130 and exposes the first type semiconductor layer 140 of the epitaxial structure E, and the second opening O2 penetrates through the first type semiconductor layer 140 and the light emitting layer 150 to expose the second type semiconductor layer 160 of the epitaxial structure E. Then, in order to electrically isolate the second electrodes (124a, referring to FIG. 1C) and the first type semiconductor layer 140, the insulation layer 130 of the present embodiment can be configured to extend into the opening 02. In another embodiment, referring to FIG. 2B, since the epitaxial structures E are separated from each other to expose a surface of the substrate 10, the insulation layer 130 can also be disposed on the surface of the substrate 10 exposed by the epitaxial structure E.

Then, referring to FIG. 1C, the electrode connection layer 120a is formed on the semiconductor wafer D, where the electrode connection layer 120a includes a plurality of connection pads 126a, a plurality of first electrodes 122a and a plurality of second electrodes 124a. The first electrodes 122a and the second electrodes 124a are separated from each other and are connected to the corresponding connection pads 126a, and are located at a same side of the epitaxial structure E, i.e. located at one side of the first type semiconductor layer 140, where the first electrodes 122a and the second electrodes 124a are electrically connected to the first type semiconductor layer 140 and the second type semiconductor layer 160 of the epitaxial structure E to define a plurality of light emitting units A. To be specific, the first electrodes 122a of the present embodiment penetrate through the insulation layer 130 to electrically connect the first type semiconductor layer 140. The second electrodes 124a penetrate through the insulation layer 130, the first type semiconductor layer 140 and the light emitting layer 150 to electrically connect the second type semiconductor layer 160. Each of the light emitting units A is composed of a part of the epitaxial structure E, a part of the connection pads 126a, at least one first electrode 122a and at least one second electrode 124a. Moreover, the first electrode 122a of the electrode connection layer 120a of the present embodiment is, for example, a P-type electrode, and the second electrode 124a is, for example, an N-type electrode, though the invention is not limited thereto. A material of the first electrode 122a and the second electrode 124a can be an alloy of materials selected from chromium, platinum, gold, or a combination of the above materials. A material of the connection pad 126a can be an alloy of materials selected from titanium, gold, indium, tin, chromium, platinum, or a combination of the above materials. It should be noticed that the first electrodes 122a, the second electrodes 124a and the connection pads 126a can be made of a same material, and can also be made of different materials, which is not limited by the invention. Particularly, referring to FIG. 1C, the electrode connection layer 120a of the present embodiment has a plurality of buffer zones S. The buffer zone S is embodied by a space. During a manufacturing process of the light emitting device, the buffer zone S can decrease a thermal stress effect under a temperature variation, so as to improve product reliability.

Then, referring to FIG. 1D(a), a package substrate 110a is provided, where the package substrate 110a has an upper surface 112 and a lower surface 114 opposite to each other and a plurality of conductive through holes 116a penetrating through the package substrate 110a. Certainly, in another embodiment, referring to FIG. 1D(b), the package substrate 110a may further include a plurality of external pads 118 electrically connected to the conductive through holes 116a and disposed on the lower surface 114 of the package substrate 110a. Alternatively, in another embodiment, referring to FIG. 1D(c), the package substrate 110a may further include a plurality of internal pads 115 electrically connected to the conductive through holes 116a and disposed on the upper surface 112 of the package substrate 110a and a plurality of external pads 118 electrically connected to the conductive through holes 116a and disposed on the lower surface 114 of the package substrate 110a. The above three patterns of the package substrate 110a are all within a protection range of the invention. In the present embodiment, a material of the internal pads 115 and the external pads 118 can be an alloy of materials selected from copper, titanium, gold, indium, tin, chromium, platinum, or a combination of the above materials, and preferably, the internal pads 115 and the electrode connection layer 120a are made of a same material to facilitate subsequent bonding, and a thermal conduction coefficient of the external pads 118 is higher than a thermal conduction coefficient of the electrode connection layer 120a to facilitate quickly conducting heat generated by the epitaxial structure E to external, so as to avoid heat accumulation to influence the performance of the expiation structure E.

To be specific, the package substrate 110a of the present embodiment substantially has a similar size as that of the semiconductor wafer D. Referring to FIG. 1E, the aforementioned “similar” refers to that due to a process margin, a contour size of the semiconductor wafer D is not necessarily identical to a contour size of the package substrate 110a, though the contour size of the semiconductor wafer D and the contour size of the package substrate 110a are approximately the same. Moreover, the package substrate 110a of the present embodiment have a better heat dissipation effect, and is, for example, a substrate with a thermal conduction coefficient greater than 10 W/m-K. The package substrate 110a can also be an insulation substrate with resistivity greater than 10¹⁰Ω·m. In the present embodiment, the package substrate 110a is, for example, a ceramic substrate or a sapphire substrate. Preferably, the package substrate 110a is a ceramic substrate with a good heat dissipation effect and insulation effect. A thickness of the package substrate 110a is, for example, between 100 μm and 700 μm, and preferably between 100 μm and 300 μm. As shown in FIG. 1D(a) to FIG. 1D(c), the conductive through holes 116a of the present embodiment is formed by filling a conductive material such as copper, gold, etc. in the through holes of the package substrate 110a. A cross-sectional profile of the conductive through hole 116a may have different shapes according to a fabrication method thereof. For example, if a mechanical drilling method is adopted, the presented cross-sectional profile of the conductive through hole 116a is a rectangle (not shown); if a laser drilling method is adopted, the presented cross-sectional profile of the conductive through hole 116a is a trapezoid, which is shown in FIG. 1D. However, if the laser drilling method is adopted, an ablation direction of laser light also influences the cross-sectional profile of the conductive through hole. For example, if the laser light irradiates the upper surface 112 of the package substrate 110a, the cross-sectional profile of the conductive through hole 116a presents an inverted trapezoid with a wide opening at top and a narrow opening at bottom (not shown); and if the laser light irradiates the lower surface 114 of the package substrate 110a, the cross-sectional profile of the conductive through hole 116a presents a trapezoid with a narrow opening at top and a wide opening at bottom, which is shown in FIG. 1D(a). The cross-sectional profiles of the conductive through hole 116a are all within a protection range of the invention, and the invention is not limited to the cross-sectional profile of the conductive through hole 116a shown in the present embodiment.

Thereafter, referring to FIG. 1E, the semiconductor wafer D and the package substrate 110a are bonded by aligning the connection pads 126a of the electrode connection layer 120a with the conductive through holes 116a, so that the conductive through holes 116a are electrically connected to the first type semiconductor layer 140 or the second type semiconductor layer 160. Namely, the conductive through holes 116a of the package substrate 110a, the internal pads 115, the electrode connection layer 120a and the external pads 118 are electrically connected. In detail, the internal pads 115 are disposed corresponding to the connection pads 126a of the electrode connection layer 120a, and an orthogonal projection of the internal pads 115 on the package substrate 110a are completely coincided with an orthogonal projection of the connection pads 126a on the package substrate 110a. Now, a bonding area between the semiconductor wafer D and the package substrate 110a is smaller than an area of the upper surface 112 of the package substrate 110a. The buffer zones S are formed between the insulation layer 130, the connection pads 126a and the package substrate 110a, and the buffer zones S can decrease a thermal stress effect of the electrode connection layer 120a and the internal pads 115 under different temperatures. Particularly, in the present embodiment, the connection pads 126a of the semiconductor wafer D are melted for bonding to the package substrate 110a through heating. Finally, referring to FIG. 1E and FIG. 1F, the substrate 10 is removed to expose a surface E1 of the epitaxial structure E, so as to complete manufacturing the light emitting device 100. Now, the package substrate 110a and the epitaxial structure E of the light emitting device 100 have similar areas, i.e. an area ratio between the epitaxial structure E and the package substrate 110a of the light emitting device 100 is close to 1. The surface E1 is, for example, a flat surface, though the invention is not limited thereto. Thereafter, an optical coupling layer 190 can be formed on the surface E1 of the epitaxial structure E according to a usage requirement, such that the light generated by the epitaxial structure E of the light emitting device 100 may have a scattering effect, so as to improve a light emitting efficiency of the whole light emitting device 100.

In order to meet demands on different sizes, after the substrate 10 is removed as shown in FIG. 1E, referring to FIG. 1F and FIG. 1G(a), a cutting process is performed to the light emitting device 100 along a cutting line L, so as to form a plurality of sub-light emitting devices 100a, where each of the sub-light emitting devices 100a includes a plurality of light emitting units A, and in collaboration with the design of the connection pads 126a, the light emitting units A have an integrated circuit design, i.e. the light emitting units A are connected in series and/or parallel, so as to effectively improve a device brightness and reduce a device volume. Alternatively, referring to FIG. 1F and FIG. 1G(b), a cutting process is performed to the light emitting device 100 to form a plurality of sub-light emitting devices 100a′, where the sub-light emitting devices 100a′ are separated from each other and an edge of the connection pad 126a of the electrode connection layer 120a is aligned with an edge of the package substrate 110a. Here, the cutting process is performed along a direction from the epitaxial structure E to the package substrate 110a. It should be noticed that the sub-light emitting devices 100a, 100a′ can be regarded as a light emitting chip.

Moreover, it should be noticed that after the substrate 10 is removed, the optical coupling layer 190 can be not added to the structure E. Referring to FIG. 1G(c), after the substrate 10 is removed, a sheet-like wavelength converting film 180a is provided, where an area of the sheet-like wavelength converting film 180a is greater than the area of the upper surface 112 of the package substrate 110a, and the sheet-like wavelength converting film 180a is bonded to the surface E1 of the epitaxial structure E of the light emitting device 100. Moreover, a thickness of the sheet-like wavelength converting film 180a of the present embodiment is between 5 μm and 80 μm, and preferably between 20 μm and 60 μm. In detail, the thickness of the sheet-like wavelength converting film 180a of the present embodiment is, for example, 1.5 to 25 times greater of the thickness of the epitaxial structure E, if less than 1.5 times, the light emitted from the epitaxial structure E directly passes through the sheet-like wavelength converting film 180a, which causes a poor converting efficiency, and if greater than 25 times, the light emitted from the epitaxial structure E is obstructed. A sum of the thickness of the sheet-like wavelength converting film 180a and the thickness of the epitaxial structure E is preferably smaller than 100 μm. Compared to the conventional light emitting device that the wavelength converting layer has a thickness of more than 100 μm, the light emitting device 100 of the present embodiment may have a smaller volume. Moreover, in order to improve a light emitting efficiency of the whole light emitting device 100, diffusing particles or reflecting particles can be added to the sheet-like wavelength converting film 180a, so as to achieve a light scattering effect and a light reflecting effect, which is still within the protection range of the invention. In addition, since the sheet-like wavelength converting film 180a of the present embodiment is embodied by a planar structure, a light emitting angle of the whole light emitting device 100 is, for example, smaller than 140 degrees, such that the light emitting device 100 has a good light source collimation property, and has good flexibility in application of subsequent optical design. In order to evenly mixing the light emitted by the epitaxial structure E and the light converted by the sheet-like wavelength converting film 180a, a color mixing layer 240 can be formed on the sheet-like wavelength converting film 180a to effectively improve a whole light emitting uniformity of the light emitting device 100. Certainly, the color mixing layer 240 can also be not added, and after the sheet-like wavelength converting film 180a is formed, a cutting process is performed, by which a same cutting device is used to cut the sheet-like wavelength converting film 180a and the light emitting device 100 to form a plurality of sub-light emitting devices 100a″ (referring to FIG. 1H). Here, the cutting process is performed along a direction from the sheet-like wavelength converting film 180a to the package substrate 110a. It should be noticed that cutting performed by the “same cutting device” refers to that a same cutting device (for example, laser or diamond knife) is used to cut the sheet-like wavelength converting film 180a and the light emitting device 100. Moreover, the sub-light emitting device 100a″ can be regarded as a light emitting chip.

In another embodiment, referring to FIG. 2C, since the insulation layer 130 is disposed on the surface of the substrate 10 exposed by the epitaxial structure E, in a structure obtained after the steps shown in FIG. 1C to FIG. 1F, a surface of the insulation layer 130 is aligned with the surface E1 of the epitaxial structure E. Namely, the area of the epitaxial structure E is slightly smaller than the area of the package substrate 110a, and preferably an area ratio between the epitaxial structure E of the light emitting device 100 and the package substrate 110a is between 0.75 and 0.97. Thereafter, a cutting process can be performed along a cutting line L to form a plurality of sub-light emitting devices 100a′″, and the sub-light emitting device 100a′″ can be regarded as a light emitting chip. In detail, if the area ratio between the epitaxial structure E and the package substrate 110a is higher than 0.97, a width of the insulation layer 130 is inadequate, and when the cutting process is performed, the epitaxial structure E near the insulation layer 130 is spoiled, and if the area ratio is lower than 0.75, a light emitting region is insufficient, such that the device brightness is insufficient.

In the present embodiment, the semiconductor wafer D having the epitaxial structure E formed with the electrode connection layer 120a is bonded to the package substrate 110a through wafer bonding, and then the substrate 10 is removed to form the light emitting device 100 with the area of the package substrate 110a close to the area of the epitaxial structure E, and based on power supplied by an external circuit, the light emitting device can be used. Compared to a conventional light emitting package in which electrodes of a single light emitting chip are electrically connected to pads on a larger carrier, and power is supplied to the pads through the external circuit, the light emitting device 100 with a smaller volume is manufactured according to the method for manufacturing the light emitting device 100 of the invention. Moreover, since the method for manufacturing the light emitting device 100 of the invention is to perform the cutting process after bonding the semiconductor wafer D to the package substrate 110a, the invention is adapted to simultaneously fabricate a plurality of sub-light emitting devices 100a, 100a′, 100a″, 100a′″, and the sub-light emitting devices 100a, 100a′, 100a″, 100a′″ only have one cutting mark, so as to achieve better product reliability.

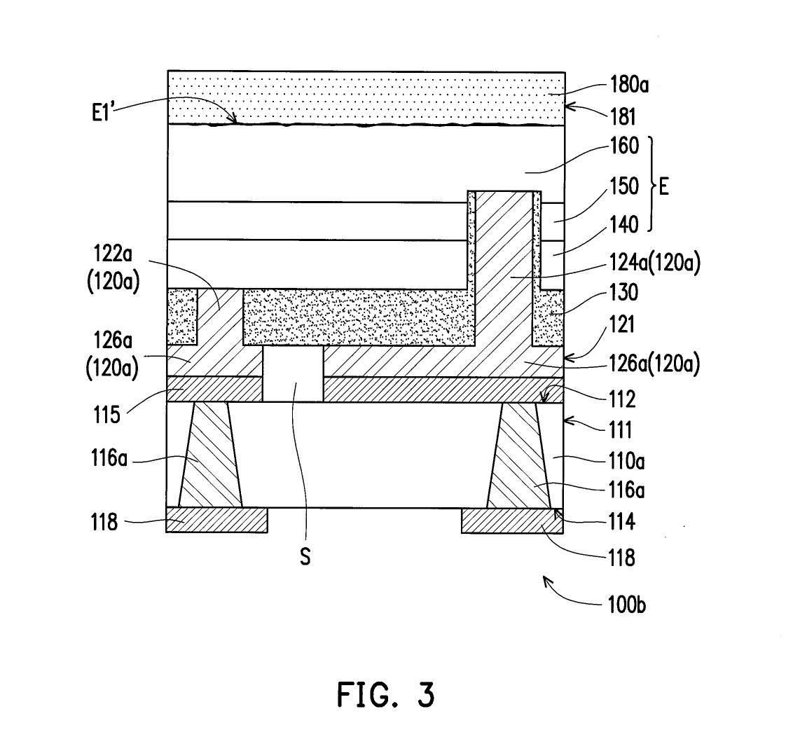

It should be noticed that reference numbers of the components and a part of contents of the aforementioned embodiment are also used in the following embodiment, wherein the same reference numbers denote the same or like components, and descriptions of the same technical contents are omitted. The aforementioned embodiment can be referred for descriptions of the omitted parts, and detailed descriptions thereof are not repeated in the following embodiment. For simplicity's sake, in FIG. 3 to FIG. 12, a single sub-light emitting device is taken as an example for description, though the invention is not limited thereto.

FIG. 3 is a cross-sectional view of a sub-light emitting device according to another embodiment of the invention. Referring to FIG. 1H and FIG. 3, the sub-light emitting device 100b of the present embodiment is similar to the sub-light emitting device 100a″ of FIG. 1H, and a main difference therebetween is that the surface of the epitaxial structure E of the sub-light emitting device 100b is embodied by a rough surface E1′, and the rough surface E1′ and the sheet-like wavelength converting film 180a have micron-scale voids therebetween. Namely, the surface of the epitaxial structure E contacting the sheet-like wavelength converting film 180a is not a flat surface, and according to such design, the light generated by the epitaxial structure E has a scattering effect, so as to effectively improve the light emitting efficiency of the sub-light emitting device 100b. Moreover, the micron-scale voids between the epitaxial structure E and the sheet-like wavelength converting film 180a can serve as a buffer therebetween, so as to improve reliability of the sub-light emitting device 100b. If the size of the voids is smaller than the micro-scale, for example, smaller than 0.1 μm, the scattering effect is not good, and if the size of the voids is greater than the micro-scale, for example, greater than 10 μm, the voids are too large, and a bonding area between the epitaxial structure E and the sheet-like wavelength converting film 180a is too small, such that a bonding effect is not good. In addition, the sub-light emitting devices 100b of the present embodiment are obtained by cutting the light emitting device 100, and since a same cutting device is used to implement the cutting process, an edge 181 of the sheet-like wavelength converting film 180a, an edge 121 of the connection pad 126a and an edge 111 of the package substrate 110a are aligned.

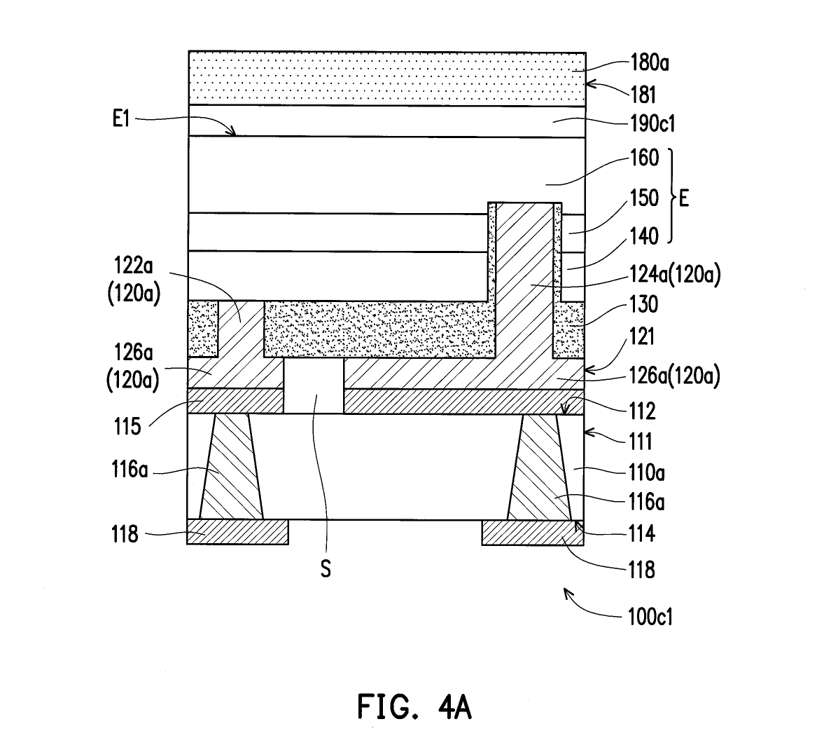

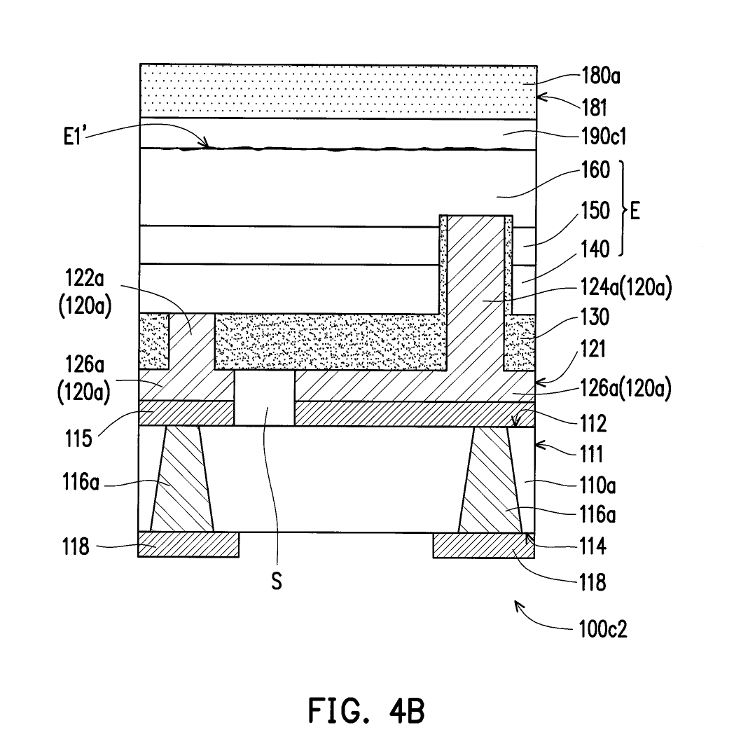

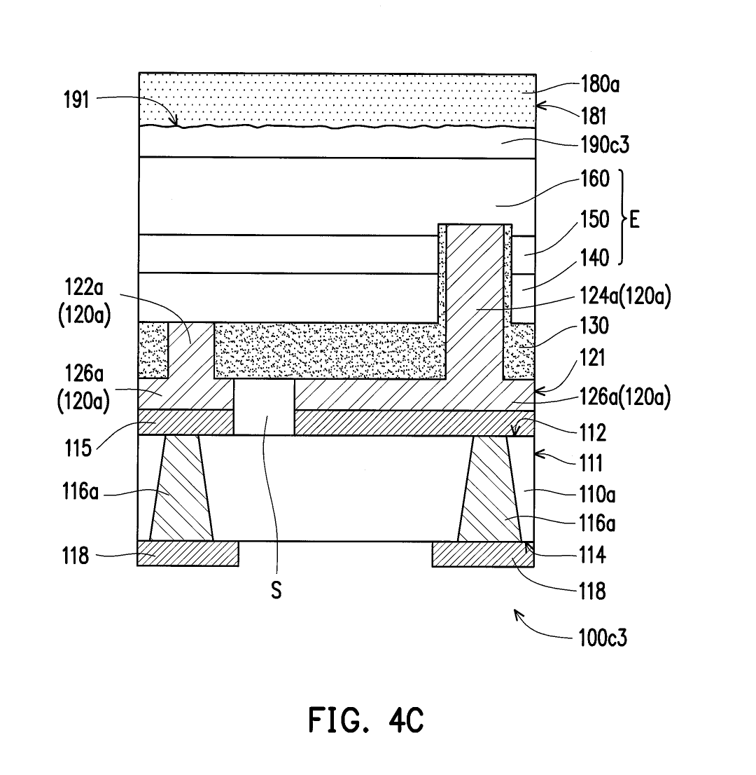

FIG. 4A is a cross-sectional view of a sub-light emitting device according to another embodiment of the invention. Referring to FIG. 3 and FIG. 4A, the sub-light emitting device 100c1 of the present embodiment is similar to the sub-light emitting device 100b of FIG. 3, and a main difference therebetween is that after the substrate 10 is removed and before the sheet-like wavelength converting film 180a is formed, an optical coupling layer 190c1 is formed on the surface E1 of the epitaxial structure E, where the optical coupling layer 190c1 is located between the sheet-like wavelength converting film 180a and the epitaxial structure E. Now, an edge of the optical coupling layer 190c1 is aligned with an edge of the second type semiconductor layer 160 of the epitaxial structure E. To be specific, the optical coupling layer 190c1 is disposed between the sheet-like wavelength converting film 180a and the second type semiconductor layer 160 of the epitaxial structure E, and is configured to increase a light emitting efficiency of the sub-light emitting device 100c1. Here, the optical coupling layer 190c1 has a thickness smaller than 10 μm, and can serve as a buffer between the epitaxial structure E and the sheet-like wavelength converting film 180a, and implement a good bonding effect between the epitaxial structure E and the sheet-like wavelength converting film 180a. Moreover, a material of the optical coupling layer 190c1 of the present embodiment is, for example, gallium nitride. Alternatively, the material of the optical coupling layer 190c1 is substantially the same to the material of the second type semiconductor layer 160, so as to achieve a good bonding effect, though the invention is not limited thereto. Moreover, in order to improve the light emitting efficiency of the sub-light emitting device 100c1, the optical coupling layer 190c1 may adopt a material having a similar refractive index with that of the second type semiconductor layer 160, and by adding diffusing particles, reflecting particles, scattering particles or at least two of the above particles to the optical coupling layer 190c1, the light generated by the epitaxial structure E may have a diffusing, reflecting and scattering effects. Moreover, the refractive index of the optical coupling layer 190c1 can be changed, such that the refractive index of the optical coupling layer 190c1 is smaller than the refractive index of the second semiconductor layer 160 and is greater than the refractive index of the sheet-like wavelength converting film 180a, so as to decrease a total reflection effect to increase a light emitting efficiency, which is still considered to be within the protection range of the invention.

FIG. 4B is a cross-sectional view of a sub-light emitting device according to another embodiment of the invention. Referring to FIG. 4A and FIG. 4B, the sub-light emitting device 100c2 of the present embodiment is similar to the sub-light emitting device 100c1 of FIG. 4A, and a main difference therebetween is that the epitaxial structure E of the sub-light emitting device 100c2 has the rough surface E1′, and the rough surface E1′ and the optical coupling layer 190c1 have micron-scale voids therebetween. Namely, the surface of the epitaxial structure E contacting the optical coupling layer 190c1 is not a flat surface, and according to such design, the light generated by the epitaxial structure E has a scattering effect, so as to effectively improve the light emitting efficiency of the sub-light emitting device 100c2. Moreover, the micron-scale voids between the epitaxial structure E and the optical coupling layer 190c1 can serve as a buffer therebetween. If the size of the voids is smaller than the micro-scale, for example, smaller than 0.1 μm, the scattering effect is not good, and if the size of the voids is greater than the micro-scale, for example, greater than 10 μm, the voids are too large, and a bonding area between the epitaxial structure E and the optical coupling layer 190c1 is too small, such that a bonding effect is not good.

FIG. 4C is a cross-sectional view of a sub-light emitting device according to another embodiment of the invention. Referring to FIG. 4C and FIG. 4A, the sub-light emitting device 100c3 of the present embodiment is similar to the sub-light emitting device 100c1 of FIG. 4A, and a main difference therebetween is that the optical coupling layer 190c3 of the sub-light emitting device 100c3 has a rough surface 191, and the rough surface 191 and the sheet-like wavelength converting film 180a have micron-scale voids therebetween. Namely, the surface of the optical coupling layer 190c3 contacting the sheet-like wavelength converting film 180a is not a flat surface, and according to such design, the light generated by the epitaxial structure E has a scattering effect, so as to effectively improve the light emitting efficiency of the sub-light emitting device 100c3. Moreover, the micron-scale voids between the optical coupling layer 190c3 and the sheet-like wavelength converting film 180a can serve as a buffer space between the two different layers, such that the epitaxial structure E and the sheet-like wavelength converting film 180a have a good bonding effect therebetween, so as to improve the reliability of the sub-light emitting device 100c3. Particularly, the optical coupling layer 190c3 may have two rough surfaces, i.e. the optical coupling layer 190c3 and the sheet-like wavelength converting film 180a have the micron-scale voids therebetween, and the optical coupling layer 190c3 and the epitaxial structure E also have the micron-scale voids therebetween (not shown), which is not limited by the invention. Here, if the size of the voids is smaller than the micro-scale, for example, smaller than 0.1 μm, the scattering effect is not good, and if the size of the voids is greater than the micro-scale, for example, greater than 10 μm, the bonding area is too small, such that a bonding effect is not good.

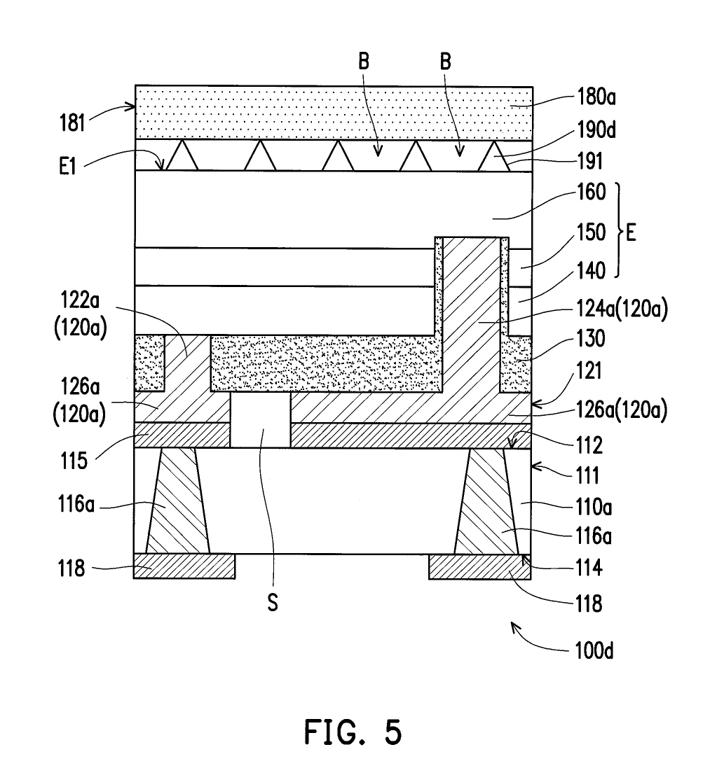

FIG. 5 is a cross-sectional view of a sub-light emitting device according to another embodiment of the invention. Referring to FIG. 5 and FIG. 3, the sub-light emitting device 100d of the present embodiment is similar to the sub-light emitting device 100b of FIG. 3, and a main difference therebetween is that after the substrate 10 is removed and before the sheet-like wavelength converting film 180a is formed, an optical coupling layer 190d is formed on the surface E1 of the epitaxial structure E, where the optical coupling layer 190d is located between the sheet-like wavelength converting film 180a and the second type semiconductor layer 160 of the epitaxial structure E, and has a patterned rough surface 191. The optical coupling layer 190d and the sheet-like wavelength converting film 180a have at least one space B therebetween. As shown in FIG. 5, a profile pattern of the optical coupling layer 190d of the present embodiment is, for example, periodic triangle patterns, and the space B exists between two adjacent triangle patterns. Certainly, in other embodiment that is not illustrated, the profile pattern of the optical coupling layer can be other patterns that are not periodically arranged, which is also within the protection range of the invention. Since the optical coupling layer 190d and the sheet-like wavelength converting film 180a have a non-flat contact, based on such design, the light generated by the epitaxial structure E has the scattering effect, so as to improve the light emitting efficiency of the whole sub-light emitting device 100d. Moreover, the space between the optical coupling layer 190d and the sheet-like wavelength converting film 180a can serve as a buffer space between two different layers, such that the epitaxial structure E and the sheet-like wavelength converting film 180a have a good bonding effect therebetween, so as to improve the reliability of the sub-light emitting device 100d. Here, if the size of the space B is smaller than the micro-scale, for example, smaller than 0.1 μm, the scattering effect is not good, and if the size of the space B is greater than the micro-scale, for example, greater than 10 μm, the bonding area is too small, such that a bonding effect is not good.

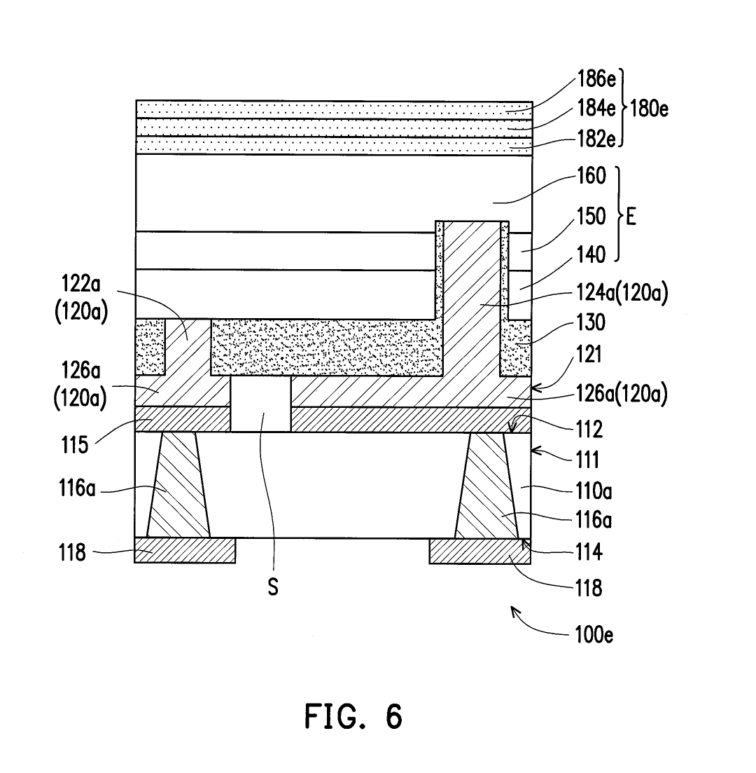

FIG. 6 is a cross-sectional view of a sub-light emitting device according to another embodiment of the invention. Referring to FIG. 6 and FIG. 3, the sub-light emitting device 100e of the present embodiment is similar to the sub-light emitting device 100b of FIG. 3, and a main difference therebetween is that the sheet-like wavelength converting film 180e of the sub-light emitting device 100e includes at least two sheet-like wavelength converting unit layers, and main emission wavelengths of the sheet-like wavelength converting unit layers are progressively decreased along a direction away from the epitaxial structure E. In the present embodiment, the at least two sheet-like wavelength converting unit layers are three sheet-like wavelength converting unit layers, and the sheet-like wavelength converting unit layers include a first sheet-like wavelength converting unit layer 182e, a second sheet-like wavelength converting unit layer 184e and a third sheet-like wavelength converting unit layer 186e sequentially stacked on the epitaxial structure E. The main emission wavelength of the first sheet-like wavelength converting unit layer 182e is greater than the main emission wavelength of the second sheet-like wavelength converting unit layer 184e, and the main emission wavelength of the second sheet-like wavelength converting unit layer 184e is greater than the main emission wavelength of the third sheet-like wavelength converting unit layer 186e. For example, when the epitaxial structure E emits a blue light, the first sheet-like wavelength converting unit layer 182e is, for example, a red light wavelength converting unit layer, the second sheet-like wavelength converting unit layer 184e is, for example, a yellow light wavelength converting unit layer, and the third sheet-like wavelength converting unit layer 186e is, for example, a green light wavelength converting unit layer, by which light emitting uniformity and color rendering of the whole sub-light emitting device 100e are enhanced. Certainly, in other embodiments, the first sheet-like wavelength converting unit layer 182e, the second sheet-like wavelength converting unit layer 184e and the third sheet-like wavelength converting unit layer 186e can be sheet-like wavelength converting films of other colors, and the colors and the arrangement sequence of the main wavelengths thereof are not limited by the invention. Particularly, an extending direction of the first sheet-like wavelength converting unit layer 182e, the second sheet-like wavelength converting unit layer 184e and the third sheet-like wavelength converting unit layer 186e is the same to an extending direction of the package substrate 110a. The first sheet-like wavelength converting unit layer 182e, the second sheet-like wavelength converting unit layer 184e, the third sheet-like wavelength converting unit layer 186e and the package substrate 110a are all laterally extended planar structures, such that the whole sub-light emitting device 100e has a smaller volume.

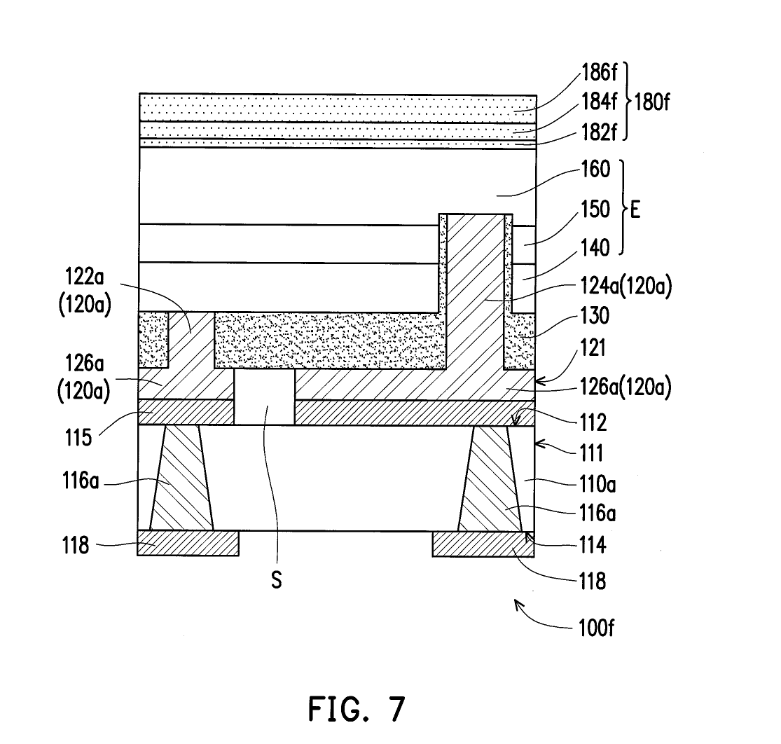

FIG. 7 is a cross-sectional view of a sub-light emitting device according to another embodiment of the invention. Referring to FIG. 7 and FIG. 6, the sub-light emitting device 100f of the present embodiment is similar to the sub-light emitting device 100e of FIG. 6, and a main difference therebetween is that in the sheet-like wavelength converting film 180f of the present embodiment, a thickness of the first sheet-like wavelength converting unit layer 182f, a thickness of the second sheet-like wavelength converting unit layer 184f, and a thickness of the third sheet-like wavelength converting unit layer 186f are all different. Preferably, the thickness of the first sheet-like wavelength converting unit layer 182f is 0.2 to 0.4 times of the thickness of the second sheet-like wavelength converting unit layer 184f. For example, when the first sheet-like wavelength converting unit layer 182f is a red light wavelength converting unit layer, the second sheet-like wavelength converting unit layer 184f is a yellow light wavelength converting unit layer, and the thickness of the first sheet-like wavelength converting unit layer 182f is 0.2 to 0.4 times of the thickness of the second sheet-like wavelength converting unit layer 184f, a usage amount of red phosphor powder with higher cost is decreased, so as to effectively decrease a manufacturing cost of the whole light emitting device 100f.

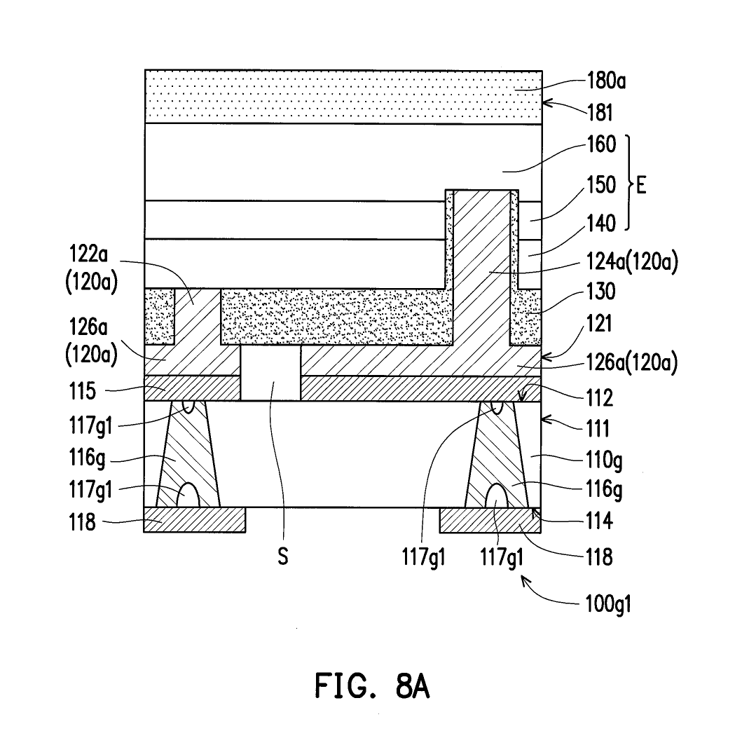

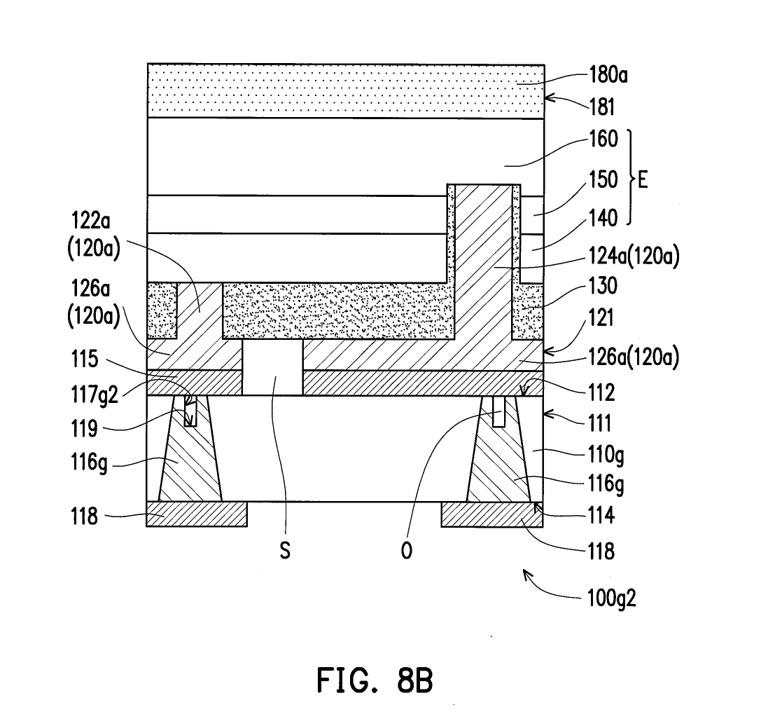

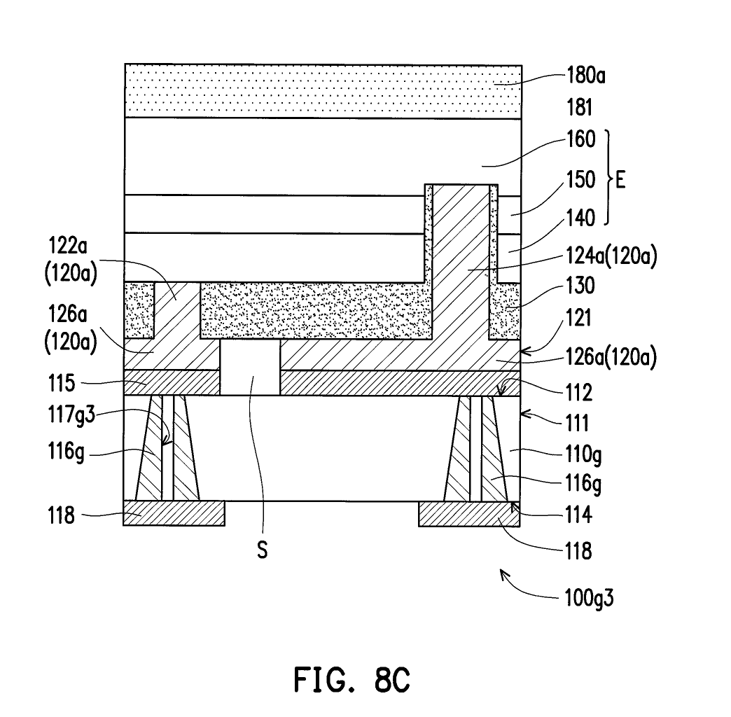

FIG. 8A is a cross-sectional view of a sub-light emitting device according to another embodiment of the invention. Referring to FIG. 8A and FIG. 3, the sub-light emitting device 100g1 of the present embodiment is similar to the sub-light emitting device 100b of FIG. 3, and a main difference therebetween is that after the semiconductor wafer D and the package substrate 110a are bonded, each of the conductive through holes 116g and the corresponding connection pad 126a have at least one space therebetween. In detail, each of the conductive through holes 116g of the substrate 110g has at least one space 117g1 (two spaces 117g1 are schematically illustrated in FIG. 8A), where the spaces 117g1 can serve as buffers between the conductive through hole 116g and the electrode connection layer 120a, between the conductive through hole 116g and the internal pad 115, and between the conductive through hole 116g and the external pad 118. The spaces 117g1 in FIG. 8A can be close to or connected to the upper surface 112 or the lower surface 114 of the package substrate 110g, though the invention is not limited thereto.

FIG. 8B is a cross-sectional view of a sub-light emitting device according to another embodiment of the invention. Referring to FIG. 8B and FIG. 8A, the sub-light emitting device 100g2 of the present embodiment is similar to the sub-light emitting device 100g1 of FIG. 8A, and a main difference therebetween is that the space 117g2 of each of the conductive through holes 116g of the present embodiment extends along a direction from the upper surface 112 of the package substrate 110g to the lower surface 114 thereof and has a bottom surface 119. Namely, the space 117g2 of each of the conductive through holes 116g has an opening O facing the upper surface 112. The opening O connects the conductive through hole 116g and the electrode connection layer 120a, and can serve as a buffer between two layers with different thermal expansion coefficients such as the conductive through hole 116g and the electrode connection layer 120a under different temperature variation processes.

FIG. 8C is a cross-sectional view of a sub-light emitting device according to another embodiment of the invention. Referring to FIG. 8C and FIG. 8A, the sub-light emitting device 100g3 of the present embodiment is similar to the sub-light emitting device 100g1 of FIG. 8A, and a main difference therebetween is that the space 117g3 of each of the conductive through holes 116g of the present embodiment is a through hole penetrating through the substrate 110g and connecting the upper surface 112 and the lower surface 114. In other embodiments that are not illustrate, the space can exist in the conductive through hole 116g without contacting the electrode connection layer 120a or the internal and external pads 115 and 118, and it is considered to be within the scope of the invention as long as a space exists between the conductive through hole 116a and the electrode connection layer 120a or between the internal, external pads 115 and 118 to serve as a buffer.

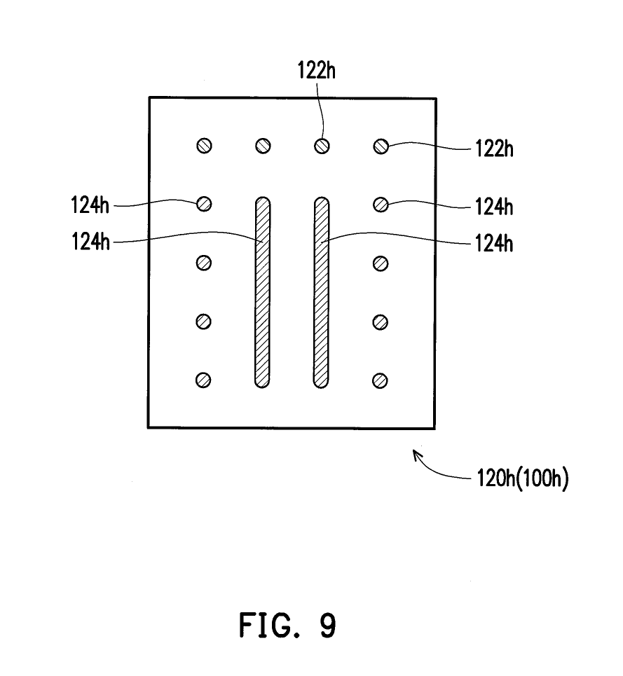

FIG. 9 is a top view of an electrode connection layer of a sub-light emitting device according to another embodiment of the invention. The electrode connection layer 120h of the present embodiment has a plurality of first electrodes 122h and a plurality of second electrodes 124h, where a top-view contour of each of the first electrodes 122h is a dot-like profile, and a top-view contour of the second electrodes 124h is a combination of a dot-like profile and a linear profile. The second electrodes 124h of the present embodiment simultaneously have electrodes with a dot-like contour and electrodes with a linear contour, and as shown in FIG. 9, these electrode patterns are separated from each other. Since the second electrodes 124h of in the sub-light emitting device 100h of the present embodiment have the electrode patterns with dot-like and linear contours, a current distribution can be more even and a forward voltage can be effectively decreased.

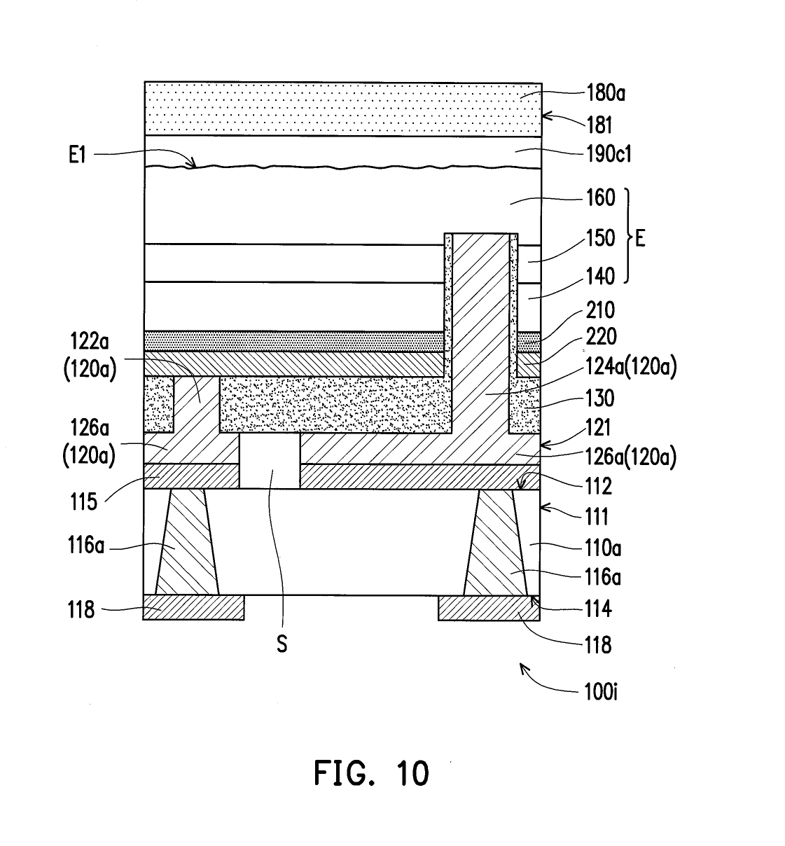

FIG. 10 is a cross-sectional view of a sub-light emitting device according to another embodiment of the invention. Referring to FIG. 10 and FIG. 4B, the sub-light emitting device 100i of the present embodiment is similar to the sub-light emitting device 100c2 of FIG. 4B, and a main difference therebetween is that before the insulation layer 130 is formed, an ohmic contact layer 210 is further formed on the first type semiconductor layer 140, where the ohmic contact layer 210 is located between the first type semiconductor layer 140 and the insulation layer 130. Moreover, in the present embodiment, after the ohmic contact layer 210 is formed, a reflection layer 220 can be further formed on the ohmic contact layer 210, where the reflection layer 220 is located between the ohmic contact layer 210 and the insulation layer 130. Thereafter, after the semiconductor wafer and the package substrate are bonded, a cutting process is performed to form a plurality of sub-light emitting devices 100i of FIG. 10. Here, configuration of the ohmic contact layer 210 can effectively enhance electrical contact between the first type semiconductor layer 140 and the reflection layer 220, where a material of the ohmic contact layer 210 is, for example, nickel or nickel oxide. A material of the reflection layer 220 is, for example, silver, which is adapted to reflect the light of the light emitting layer 150 to achieve a good light emitting efficiency. Particularly, the ohmic contact layer 210 may have a profile pattern embodied by a non-periodic island-shaped pattern (not shown), i.e. spaces exist between the ohmic contact layer 210 and the first type semiconductor layer 140 and between the first electrode 122a and the reflection layer 220, which avails increasing electrically connection and bonding between the ohmic contact layer 210 and the first type semiconductor layer 140 and between the first electrode 122a and the reflection layer 220. Moreover, a thickness of the ohmic contact layer 210 and a thickness of the reflection layer 220 of the present embodiment is, for example, between 1000 Å and 7000 Å, and preferably between 1000 Å and 3500 Å.

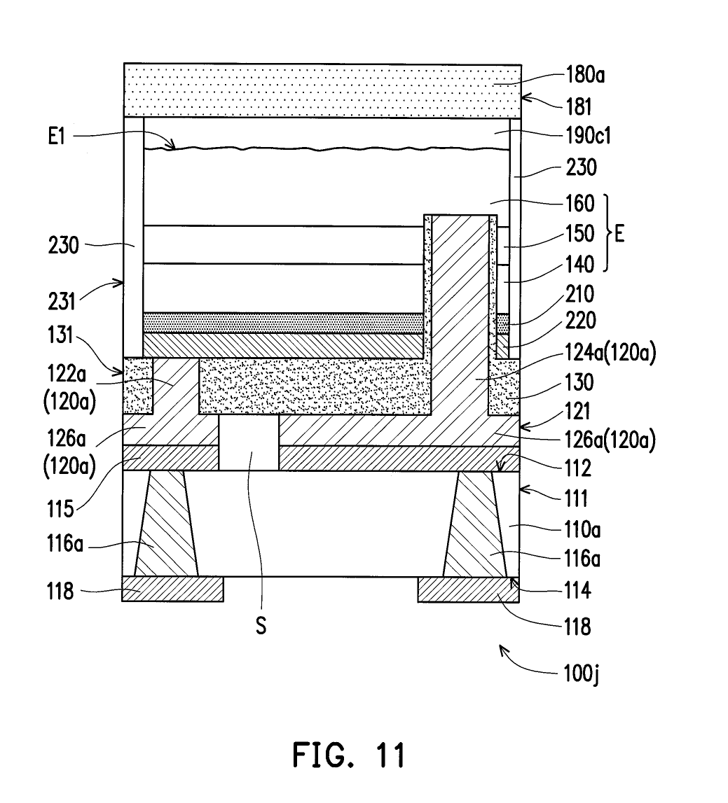

FIG. 11 is a cross-sectional view of a sub-light emitting device according to another embodiment of the invention. Referring to FIG. 11 and FIG. 10, the sub-light emitting device 100j of the present embodiment is similar to the sub-light emitting device 100i of FIG. 10, and a main difference therebetween is that after the substrate 10 is removed, an insulation protection layer 230 is formed to cover the edge of the first type semiconductor layer 140, the edge of the light emitting layer 150 and the edge of the second type semiconductor layer 160. Thereafter, a cutting process is performed to form a plurality of sub-light emitting devices 100j of FIG. 11. An edge 231 of the insulation protection layer 230 is aligned with an edge 131 of the insulation layer 130. The insulation protection layer 230 is configured to effectively protect the edge of the epitaxial structure E, so as to avoid invasion of vapor and oxygen, and effectively improve product reliability of the whole sub-light emitting device 100j. Particularly, the insulation protection layer 230 of the present embodiment further covers edges of the optical coupling layer 190c1, the ohmic contact layer 210 and the reflection layer 220, so as to achieve better reliability of the sub-light emitting device 100j.

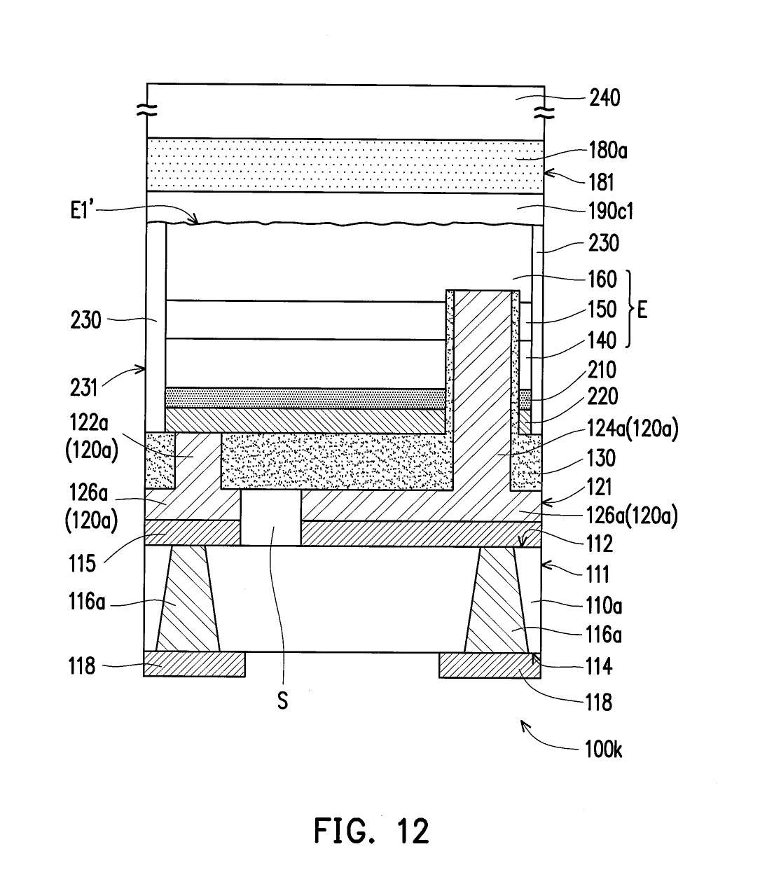

FIG. 12 is a cross-sectional view of a sub-light emitting device according to another embodiment of the invention. Referring to FIG. 12 and FIG. 11, the sub-light emitting device 100k of the present embodiment is similar to the sub-light emitting device 100j of FIG. 11, and a main difference therebetween is that after the sheet-like wavelength converting film 180a is formed, a color mixing layer 240 is further formed on the sheet-like wavelength converting film 180a. Thereafter, a cutting process is performed to form a plurality of sub-light emitting devices 100k of FIG. 12. In the present embodiment, the color mixing layer 240 is made of a transparent material, for example, glass, sapphire, epoxy resin or silicon, and a thickness of the color mixing layer 240 is greater than 100 μm. Namely, the thickness of the color mixing layer 240 is greater than the thickness of the epitaxial structure E plus the thickness of the sheet-like wavelength converting film 180a. The color mixing layer 240 with a thicker thickness can be regarded as a light guiding layer, and can uniformly mix the light emitted by the epitaxial structure E and converted by the sheet-like wavelength converting film 180a, so as to effectively enhance the light emitting uniformity of the sub-light emitting device 100k.

In summary, the semiconductor wafer having the epitaxial structure formed with the electrode connection layer is bonded to the package substrate through wafer bonding, and then the substrate is removed to form the light emitting device with the area of the package substrate close to the area of the epitaxial structure. Then, the light emitting device is cut, and the edge of the epitaxial structure of each sub-light emitting device is substantially aligned with the edge of the package substrate, and based on power supplied by an external circuit, the light emitting device can be used. Compared to a conventional light emitting package in which electrodes of a light emitting chip are electrically connected to pads on a larger carrier, and power is supplied to the pads through the external circuit, the light emitting device with a smaller volume is manufactured according to the method for manufacturing the light emitting device of the invention. Moreover, since the method for manufacturing the light emitting device of the invention is to perform the cutting process after bonding the semiconductor wafer to the package substrate, the invention is adapted to simultaneously fabricate a plurality of sub-light emitting devices, and the sub-light emitting devices only have one cutting mark.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A method for manufacturing a light emitting device, comprising:
step (a): providing a semiconductor wafer comprising a substrate and at least one epitaxial structure, wherein the epitaxial structure comprises:
a first type semiconductor layer;
a second type semiconductor layer, disposed on the substrate, wherein the first type semiconductor layer is located on the second type semiconductor layer; and
a light emitting layer, disposed between the first type semiconductor layer and the second type semiconductor layer;
step (b): forming an electrode connection layer on the epitaxial structure, wherein the electrode connection layer comprises a plurality of connection pads, a plurality of first electrodes and a plurality of second electrodes, the first electrodes and the second electrodes are separated from each other and are connected to the corresponding connection pads, and are located at a same side of the epitaxial structure, wherein the first electrodes and the second electrodes are electrically connected to the first type semiconductor layer and the second type semiconductor layer to define a plurality of light emitting units;
step (c): providing a package substrate having a similar size as that of the semiconductor wafer, wherein the package substrate has a plurality of conductive through holes penetrating through the package substrate;
step (d): bonding the semiconductor wafer and the package substrate by aligning the connection pads of the electrode connection layer with the conductive through holes, so that the conductive through holes are electrically connected to the first type semiconductor layer or the second type semiconductor layer; and
step (e): removing the substrate to expose a surface of the epitaxial structure, so as to form the light emitting device.

2. The method for manufacturing the light emitting device as claimed in claim 1, further comprising:
step (f-1): after the step (e), performing a cutting process to the light emitting device to form a plurality of sub-light emitting devices, wherein each of the sub-light emitting devices comprises a plurality of the light emitting units.

3. The method for manufacturing the light emitting device as claimed in claim 1, further comprising:
step (f-2): after the step (e), performing a cutting process to the light emitting device to form a plurality of sub-light emitting devices, wherein the sub-light emitting devices are separated from each other and an edge of the connection pad of the electrode connection layer is aligned with an edge of the package substrate.

4. The method for manufacturing the light emitting device as claimed in claim 1, further comprising:
step (f-3): after the step (e), providing a sheet-like wavelength converting film, wherein an area of the sheet-like wavelength converting film is greater than that of the package substrate, and the sheet-like wavelength converting film is bonded to the surface of the epitaxial structure of the light emitting device.

5. The method for manufacturing the light emitting device as claimed in claim 4, wherein in the step (f-3), the sheet-like wavelength converting film and the epitaxial structure have micron-scale voids therebetween.

6. The method for manufacturing the light emitting device as claimed in claim 4, wherein in the step (f-3), after the sheet-like wavelength converting film is bonded to the surface of the epitaxial structure of the light emitting device, the method further comprises:
forming a color mixing layer on the sheet-like wavelength converting film.

7. The method for manufacturing the light emitting device as claimed in claim 4, further comprising:
step (g): after the step (f-3), performing a cutting process, and using a same cutting device to cut the sheet-like wavelength converting film and the light emitting device to form a plurality of sub-light emitting devices.

8. The method for manufacturing the light emitting device as claimed in claim 7, wherein the step (g) is performed in a direction from the sheet-like wavelength converting film to the package substrate.

9. The method for manufacturing the light emitting device as claimed in claim 1, wherein in the step (b), before the electrode connection layer is formed, the method further comprises:
forming an insulation layer on the first type semiconductor layer, wherein the first electrode penetrates through the insulation layer and is electrically connected to the first type semiconductor layer, the second electrode penetrates through the insulation layer, the first type semiconductor layer and the light emitting layer and is electrically connected to the second type semiconductor layer.

10. The method for manufacturing the light emitting device as claimed in claim 1, wherein in the step (d), the connection pads of the semiconductor wafer are melt through heating for bonding to the package substrate.

11. The method for manufacturing the light emitting device as claimed in claim 1, wherein in the step (d), a bonding area between the semiconductor wafer and the package substrate is smaller than a surface area of an upper surface of the package substrate.

12. The method for manufacturing the light emitting device as claimed in claim 1, wherein in the step (e), after the surface of the epitaxial structure is exposed, the method further comprises:
forming an optical coupling layer on the surface of the epitaxial structure.

13. The method for manufacturing the light emitting device as claimed in claim 1, wherein in the step (d), after the semiconductor wafer and the package substrate are bonded, each of the conductive through holes and the corresponding connection pad have at least one space therebetween.

14. The method for manufacturing the light emitting device as claimed in claim 1, wherein in the step (b), a contour of each of the second electrodes when viewing from atop is a combination of a dot-like profile and a linear profile, and a contour of each of the first electrodes when viewing from atop is a dot-like profile.
